(19) United States
(12) Patent Application Publication
(10) Pub. No.: US 2024/0304495 A1
(43) Pub. Date: Sep. 12, 2024

(54) HYDROGEN PLASMA TREATMENT FOR FORMING LOGIC DEVICES

(71) Applicant: Applied Materials, Inc., Santa Clara, CA (US)

(72) Inventors: Tsung-Han Yang, San Jose, CA (US); Zhen Liu, Santa Clara, CA (US); Yongqian Gao, Sunnyvale, CA (US); Michael S. Jackson, Sunnyvale, CA (US); Rongjun Wang, Dublin, CA (US)

(73) Assignee: Applied Materials, Inc., Santa Clara, CA (US)

(21) Appl. No.: 18/118,017

(22) Filed: Mar. 6, 2023

(51) Int. Cl. H01L 21/768; C23C 16/14; C23C 16/455; C23C 16/56; H01J 37/32

(52) U.S. Cl. CPC H01L 21/76862; C23C 16/14; C23C 16/45527; C23C 16/56; H01J 37/32082; H01L 21/76843; H01L 21/76876; H01L 21/76877; H01J 2237/332

(57) ABSTRACT

A method of forming a semiconductor device structure by utilizing a hydrogen plasma treatment to promote selective deposition is disclosed. In some embodiments, the method includes forming a metal layer within at least one feature on the semiconductor device structure. The method includes exposing the metal layer to a hydrogen plasma treatment. The hydrogen plasma treatment preferentially treats the top field and sidewalls while leaving the bottom surface substantially untreated to encourage bottom up metal film growth. In some embodiments, the hydrogen plasma treatment comprises substantially only hydrogen ions.

### TECHNICAL FIELD

Embodiments of the disclosure generally relate to methods for forming electronic devices. In particular, some embodiments of the disclosure provide bottom up metal gapfill.

### BACKGROUND

The fabrication of microelectronic devices typically involves a complicated process sequence requiring hundreds of individual processes performed on semi-conductive, dielectric and conductive substrates. Examples of these processes include oxidation, diffusion, ion implantation, thin film deposition, cleaning, etching, lithography among other operations. Each operation is time consuming and expensive.

With ever-decreasing critical dimensions for microelectronic devices, the design and fabrication for these devices on substrates becomes increasingly complex. Control of the critical dimensions and process uniformity becomes increasingly more significant. Complex multilayer stacks involve precise process monitoring of the critical dimensions for the thickness, roughness, stress, density, and potential defects. Multiple incremental processes in the process recipes for forming the devices ensure critical dimensions are maintained. However, each recipe process may utilize one or more process chambers that adds additional time for forming the devices in the processing systems and also provides additional opportunities for forming defects. Thus, each process adds to the overall fabrication cost for the completed microelectronic devices.

Additionally, as critical dimensions on these devices shrink, past fabrication techniques encounter new hurdles. For example, as a liner and/or nucleation layer is prepared to grow a metal gap-fill, the liner and/or nucleation layer may be thicker near the opening of the gap causing the metal fill material to close off the gap prior to completely filling the gap and resulting in seams or voids in the metal gap-fill material.

Current methods provide a selective treatment process which delays the growth of the metal fill material near the opening of the gap. However, these treatment methods can result in deposition delays on the order of minutes, leading to extended processing times, increased chemical usage and decreased throughput.

Accordingly, there is an ongoing need for improved fabrication methods to minimize cost and maximize throughput while maintaining critical dimensions for microelectronic devices.

### SUMMARY

One or more embodiments of the disclosure are directed to a method for processing a semiconductor device. The method comprises generating a hydrogen plasma within a processing region, filtering the hydrogen plasma to provide substantially only hydrogen ions, and exposing a first portion of a metal layer to the hydrogen ions to treat the first portion of the layer without treating a second portion of the layer. A metal film is selective formed on the second portion of the metal layer.

Additional embodiments of the disclosure are directed to a method of bottom-up metal gapfill. The method comprises exposing a metal nucleation layer to a hydrogen-containing plasma to form a treated portion of the nucleation layer. The nucleation layer is formed on sidewall surfaces and a bottom surface of a feature. The feature extends a depth from a top to the bottom surface and having the sidewall surfaces therebetween. The treated portion being located on the sidewall surfaces near the top. A metal film is formed on the untreated portion of the nucleation layer on the bottom surface.

Further embodiments of the disclosure are directed to a method of forming a logic device. The method comprises providing a substrate having a feature with a tungsten layer thereon. The feature extends a depth from a top surface to a bottom surface and is bounded by two sidewalls. The tungsten layer is formed on at least the two sidewalls and the bottom surface of the feature. The tungsten layer is exposed to ions from a CCP hydrogen plasma to treat a portion of the tungsten layer on the sidewalls near the top surface. A tungsten film is deposited on the untreated portion of the tungsten layer on at least the bottom surface.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a flow chart of a method for manufacturing a semiconductor device in accordance with one or more embodiments of the present disclosure.

FIGS. 2A-2H illustrate views of various stages of manufacturing a semiconductor device in accordance with one or more embodiments of the present disclosure.

FIG. 3 illustrates a schematic top view of one example of a multi-chamber processing tool in accordance with one or more embodiments of the present disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon

A “substrate surface” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates.

The term “about” as used herein means approximately or nearly and in the context of a numerical value or range set forth means a variation of ±15% or less, of the numerical value. For example, a value differing by ±14%, ±10%, ±5%, ±2%, ±1%, ±0.5%, or ±0.1% would satisfy the definition of “about.”

The substrate surface may have one or more features formed therein, one or more layers formed thereon, and combinations thereof. The shape of the feature can be any suitable shape including, but not limited to, trenches, holes and vias (circular or polygonal). As used in this regard, the term “feature” refers to any intentional surface irregularity. Suitable examples of features include but are not limited to trenches, which have a top, two sidewalls and a bottom extending into the substrate, and vias which have one or more sidewall extending into the substrate to a bottom.

The term “on” indicates that there is direct contact between elements. The term “directly on” indicates that there is direct contact between elements with no intervening elements.

As used in this specification and the appended claims, the terms “precursor”, “reactant”, “reactive gas” and the like are used interchangeably to refer to any gaseous species that can react with the substrate surface.

Embodiments of the disclosure advantageously provide methods for selectively depositing metal films on an underlying metal layer which has been selectively treated. Specific embodiments advantageously provide methods of forming a metal gapfill within a substrate feature. In some embodiments, the methods advantageously provide gapfill which is substantially free of seams and/or voids. In some embodiments, the methods advantageously provide gapfill which is deposited in a bottom up fashion. In some embodiments, the methods advantageously provide substrate treatments which provide less incubation delay than known processes. In some embodiments, the methods advantageously provide deposition methods with greater throughput.

The deposition of gap-fill metal thin films, for example, tungsten, copper, cobalt, ruthenium, or molybdenum thin films, in features with ultra-high aspect ratios is challenging. At earlier nodes, larger dimensions made metal gap-fill possible using nucleation followed by conformal chemical vapor deposition (CVD). However, as the critical dimensions of features continue to shrink, the tops of the ultra-small features are prone to overhang so the conformal process in which the film grows equally on the field region or surface closes or pinches off the opening before filling is complete, leaving voids in the metal gap-fill. Even in the absence of voids, center seams are a typical result of conformal deposition as the metal gap-fill grows from the sidewall. This incomplete fill may lead to high resistance. Metal gap-fill may also be adversely affected by the presence of impurities. The presence of fluorine-terminated (F-terminated) impurities on the surface of underlying layers, for example, liners, barriers, and/or nucleation layers, present in the feature. Other impurities such as boron, nitrogen, and oxides may also adversely affect metal gap-fill. For example, in some conventional bottom-up metal fill processes incorporating nucleation layers having contaminants, it is not uncommon to have a 15-20% resistance penalty when compared to metal gap-fill without nucleation layers.

Various embodiments provide improved metal gap-fill in features having reduced critical dimensions. Various embodiments utilize a hydrogen (H₂) plasma including hydrogen ions with the proper process conditions to achieve nearly conformal treatment inside the feature. This conformal treatment inside the feature enables bottom-up growth before losing the incubation delay at the top-field and sidewall. It has been found by the inventors that treating underlying films deposited along the top field and sidewalls with the hydrogen plasma treatment described herein provides conformal treatment of top field and sidewall. This conformal treatment delays incubation/growth of the metal film along the top field and sidewalls, which enables bottom-up growth of the metal film. The bottom-up growth provides for the growth of big grains within the feature instead of smaller grains, which are typically formed using conventional bottom-up growth approaches. The improved conformal treatment described herein provides for large grain growth, resulting in no resistance penalty, a reduced resistance penalty, or in some cases a resistance benefit. Some embodiments may provide improved Rs/Rc performance relative to conventional deposition only and overcome the Rs penalty, which is normally observed in conventional metal gap-fill.

The embodiments of the disclosure are described by way of the Figures, which illustrate processes, substrates and apparatus in accordance with one or more embodiments of the disclosure. The processes, schema and resulting substrates shown are merely illustrative of the disclosed processes, and the skilled artisan will recognize that the disclosed processes are not limited to the illustrated applications.

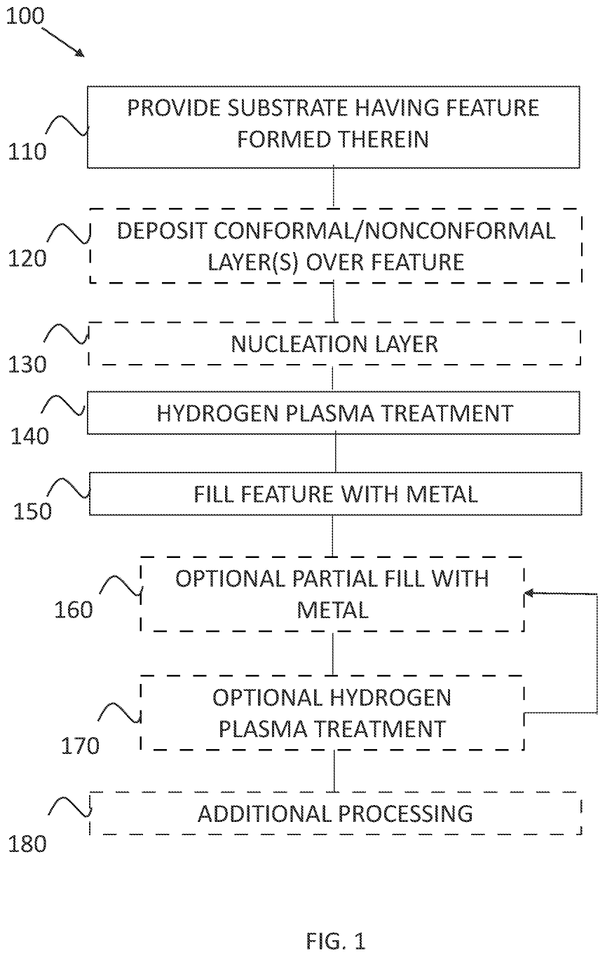

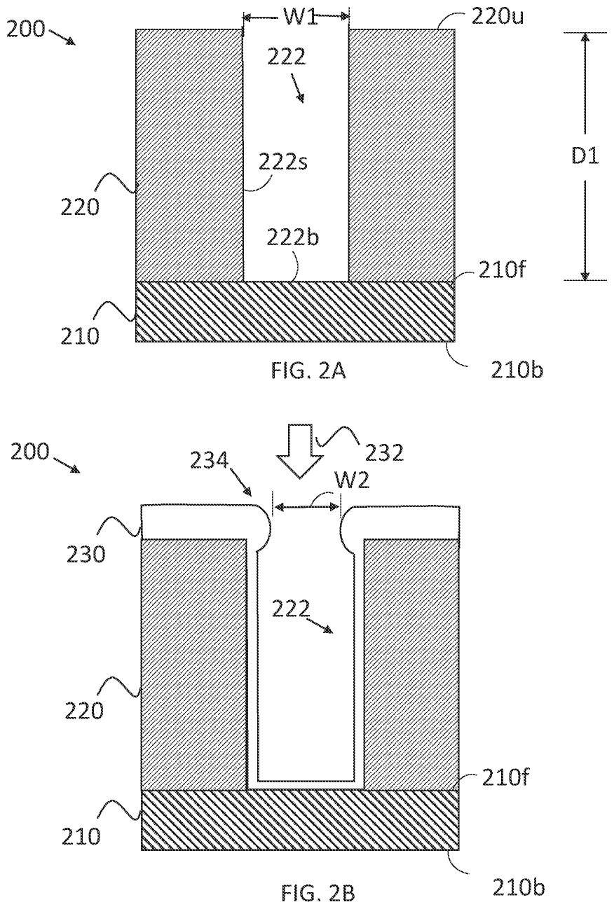

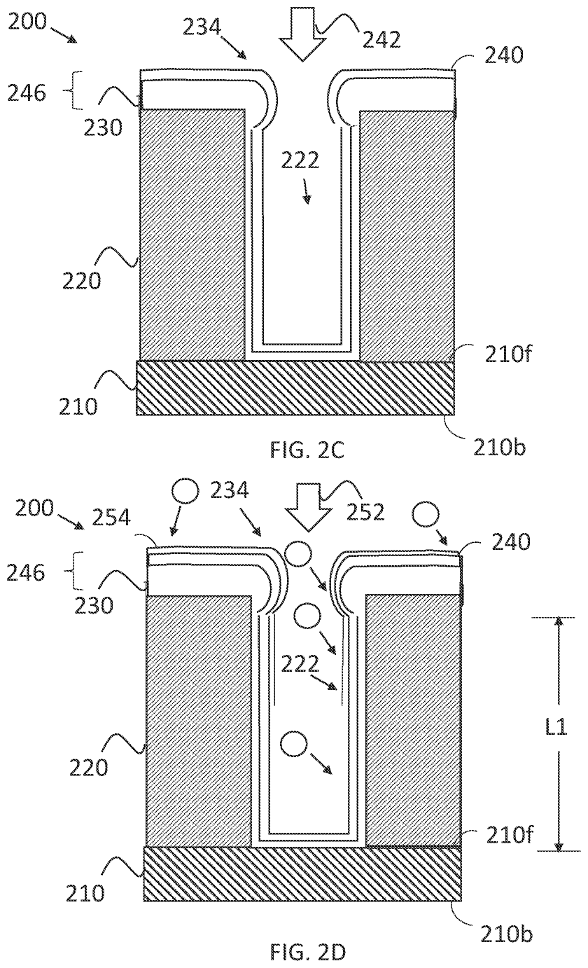

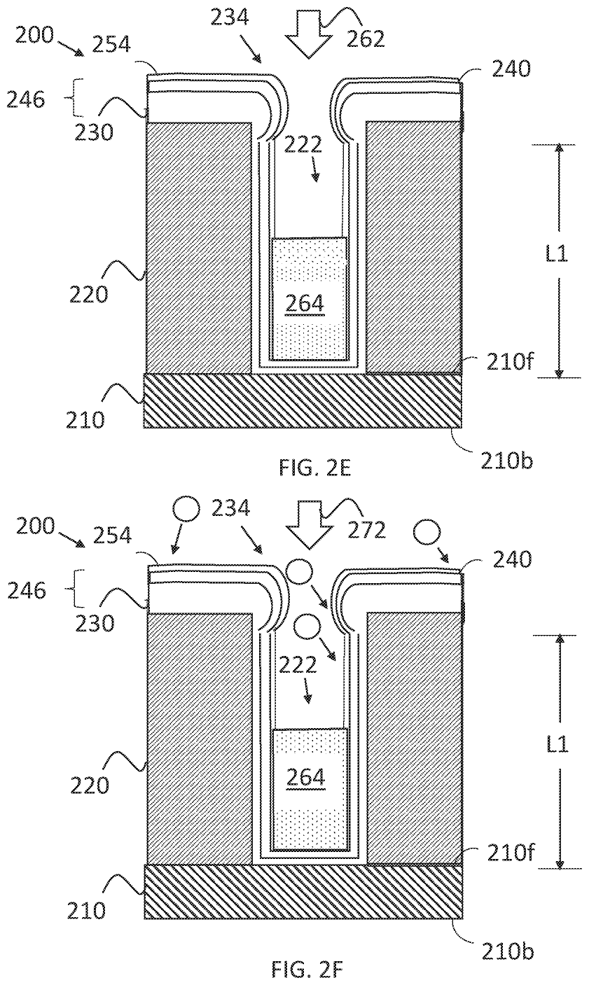

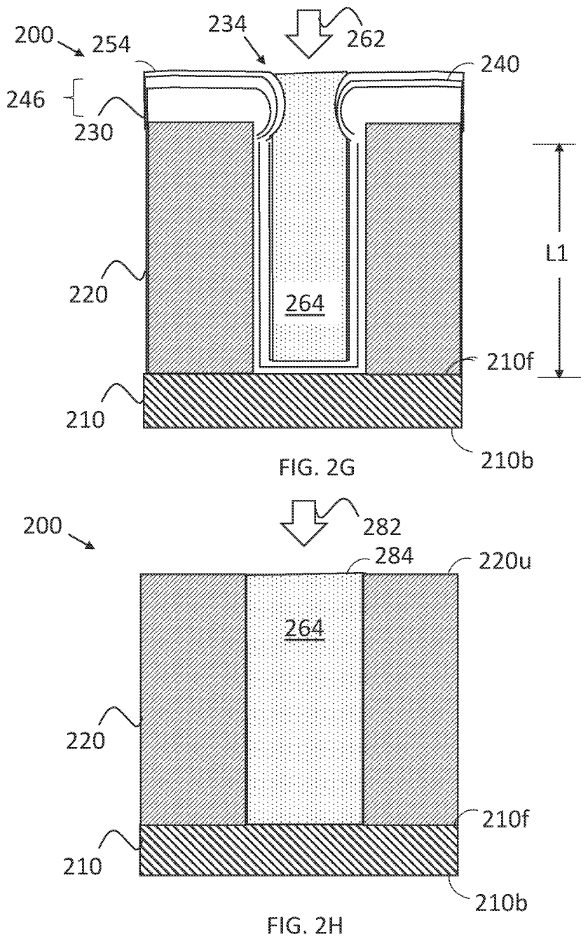

Referring to the Figures, the disclosure relates to a method 100 for manufacturing a semiconductor device. FIG. 1 depicts a process flow diagram of a method 100 in accordance with one or more embodiment of the present disclosure. FIGS. 2A-2H depict a semiconductor device structure 200 during processing according to one or more embodiment of the present disclosure.

While the Figures illustrate a specific substrate containing a feature. The methods of the disclosure are equally applicable to methods performed on substrates of different shapes, including substrates without features.

The method 100 begins with operation 110. At operation 110, a substrate is provided. The substrate may be a device substrate or a semiconductor substrate as described herein. The substrate may include multiple layers. The substrate has one or more features formed therein. The one or more features may include a sidewall surface and a bottom surface. The sidewall surface may be defined by a dielectric material and the bottom surface may be defined by a dielectric material or other materials, for example, a silicide layer, a metal silicide layer, a semiconductor layer, an etch stop layer (ESL), or a metal layer. In some embodiments, the top surface, sidewall surface and/or bottom surface may be defined by a metal material (e.g., tantalum, cobalt, titanium, tungsten, copper, ruthenium, the like, or a combination thereof).

The method 100 continues at optional operation 120. At operation 120, one or more conformal/nonconformal layers may be formed over the surfaces of the one or more features. The one or more conformal/nonconformal layers can include one or more of barrier, adhesion, and/or liner layers. The one or more conformal/nonconformal layers can include or be a nitride, for example, silicon nitride, carbon nitride, aluminum nitride, tantalum nitride, titanium nitride, tungsten nitride, the like, or a combination thereof, or a metal, for example, tantalum, cobalt, titanium, tungsten, copper, ruthenium, the like, or a combination thereof, or a carbide, for example, tungsten carbide, aluminum carbide, the like, or a combination thereof. The one or more conformal/nonconformal layers may be formed by any suitable deposition process such as ALD, CVD, PVD, or a hybrid ALD/CVD process. The one or more conformal/nonconformal layers may create an overhang portion in the field region, which obstructs or blocks top openings of the one or more features leading to the formation of seams in the metal gap-fill.

The method 100 continues at optional operation 130. At operation 130, a nucleation layer may be formed over the feature or the one or more conformal/nonconformal layers (if present). The nucleation layer may be used to repair any damage or discontinuities in the one or more conformal/nonconformal layers. The nucleation layer may be a tungsten-containing nucleation layer such as a boron-tungsten (BW) nucleation layer, a boron-silicon-tungsten (BSW) nucleation layer, or a silicon-tungsten (SW) nucleation layer. Any suitable deposition process may be used to deposit the nucleation layer. The deposition process may be an atomic layer deposition (ALD) process, a cyclic chemical vapor deposition (CCVD) process, or a combination thereof (e.g., a hybrid ALD/CVD process). In one example, one cycle of the ALD process includes a boron pulse/a boron purge/a tungsten pulse/a tungsten purge. The ALD process may be repeated for any number of cycles sufficient to deposit a nucleation layer of targeted thickness. In one example, the ALD cycle is repeated for 3 to 5 cycles. The nucleation layer may also contribute to the thickness of the overhang portion (if present).

The method 100 continues at operation 140. At operation 140, the substrate is exposed to a hydrogen plasma treatment. In some embodiments, the hydrogen plasma treatment process of operation 140 may include exposing a portion of a metal layer (e.g., the one or more conformal/nonconformal layer and/or nucleation layer) to a hydrogen plasma treatment process. In some embodiments, the hydrogen plasma treatment process is a capacitively coupled plasma process. In some embodiments, the hydrogen plasma is generated within the processing region (e.g., a direct plasma).

In some embodiments, the hydrogen plasma treatment process includes exposing the nucleation layer to a plasma formed from a process gas comprising hydrogen gas (H₂). The process gas may further include an inert gas, for example, argon (Ar), helium (He), krypton (Kr), or a combination thereof. Without being bound by theory, it is believed that some inert gas may be required within the process gas to maintain the hydrogen plasma stability.

In some embodiments, the hydrogen plasma treatment process can include exposing the metal layer to a plasma including substantially only ions (hydrogen ions). In these embodiments, operation 140 may be understood to comprise generating a hydrogen plasma and then filtering the plasma effluents to provide substantially only hydrogen ions.

The method 100 continues at operation 150. At operation 150, the one or more features may be filled with a metal film comprising tungsten, copper, cobalt, ruthenium, molybdenum, or combinations thereof. Any suitable metal film deposition process may be used to deposit the gapfill layer. The metal gap-fill layer may be deposited via a CVD gap-fill process, an ALD gap-fill process, or a hybrid ALD/CVD process. The metal gap-fill layer may partially or completely fill the one or more features. Due to the hydrogen plasma treatment process of operation 140, the clean surfaces of the underlying metal-containing layers (e.g., conformal layers and/or nucleation layer) provide for good gap-fill by the metal film with reduced Rs in the final device. In some embodiments, operation 140 and operation 150 may be repeated (shown as operation 170 and operation 160, respectively) until the metal film reaches a targeted thickness within the feature.

The method 100 continues with optional post-processing at operation 180. In some embodiments, a planarization process, for example a CMP process or an etchback process may be performed to remove excess portions or overburden of the metal film (if present). In some embodiments, an annealing process may be performed during operation 180 to densify or treat the filled feature.

With reference to FIGS. 2A-2H, cross-sectional views of some embodiments of a device structure for semiconductor devices at various stages of manufacture are provided to illustrate the method of FIG. 1. Although FIGS. 2A-2H are described in relation to the method 100, it will be appreciated that the structure disclosed in FIGS. 2A-2H are not limited to the method 100, but instead may stand alone as structures independent of method 100. Similarly, although the method 100 is described in relation to FIGS. 2A-2H, it will be appreciated that the method 100 is not limited to the structures disclosed in FIGS. 2A-2H, but instead may stand alone independent of the structures disclosed in FIGS. 2A-2H.

FIGS. 2A-2H illustrate views of various stages of manufacturing a semiconductor device in accordance with one or more embodiments of the present disclosure.

FIG. 2A illustrates a cross-sectional view of a semiconductor device structure 200 during intermediate stages of manufacturing corresponding to operation 110, in accordance with some embodiments. The semiconductor device structure 200 includes a device substrate 210 having one or more layers formed thereon, for example, a dielectric layer 220 as is shown in FIG. 2A. The device substrate 210 may be or include a bulk semiconductor substrate, a semiconductor-on-insulator (SOI) substrate, or the like, which may be doped (e.g., with a p-type dopant or an n-type dopant) or undoped. In some embodiments, the semiconductor material of the device substrate 210 may include an elemental semiconductor, for example, such as silicon (Si) or germanium (Ge); a compound semiconductor including, for example, silicon carbide, gallium arsenide, gallium phosphide, indium phosphide, indium arsenide, and/or indium antimonide; an alloy semiconductor including, for example, SiGe, GaAsP, AlInAs, GaInAs, GaInP, and/or GaInAsP; a combination thereof, or the like. The device substrate 210 may include additional materials, for example, silicide layers, metal silicide layers, metal layers, dielectric layers, etch stop layers, interlayer dielectrics, or a combination thereof.

The device substrate 210 may further include integrated circuit devices (not shown). As one of ordinary skill in the art will recognize, a wide variety of integrated circuit devices such as transistors, diodes, capacitors, resistors, the like, or combinations thereof may be formed in and/or on the device substrate 210 to generate the structural and functional requirements of the design for the resulting semiconductor device structure 200.

The device substrate 210 has a frontside 210f (also referred to as a front surface) and a backside 210b (also referred to as a back surface) opposite the frontside 210f. The dielectric layer 220 is formed over the frontside 210f of the device substrate 210. The dielectric layer 220 may include multiple layers. The dielectric layer 220 includes an upper surface 220u or top surface or field region. In some embodiments, the dielectric layer 220 includes silicon oxide, silicon oxynitride, silicon nitride, a combination thereof, or multi-layers thereof. In some embodiments, the dielectric layer 220 consists essentially of silicon oxide. It is noted that the foregoing descriptors (e.g., silicon oxide) should not be interpreted to disclose any particular stoichiometric ratio. Accordingly, “silicon oxide” and the like will be understood by one skilled in the art as a material consisting essentially of silicon and oxygen without disclosing any specific stoichiometric ratio.

The dielectric layer 220 is patterned to form one or more feature(s) 222. In some embodiments, the feature 222 can be selected from a trench, a via, a hole, or combinations thereof. In particular embodiments the feature 222 is a via. In some embodiments, the feature 222 extends from the upper surface 220u of the dielectric layer 220 to the frontside 210f of the device substrate 210. The feature 222 includes sidewall surface 222s and a bottom surface 222b extending between the sidewall surface 222s. In some embodiments, the sidewall surface 222s are tapered. The sidewall surface 222s may be defined by the dielectric layer 220 and the bottom surface may be defined by the device substrate 210. In some embodiments, the sidewall surface 222s may be defined by the dielectric layer 220 and the bottom surface may also be defined by the dielectric layer 220. The feature 222 has a first depth “D1” from the upper surface 220u to the bottom surface 222b and a width “W1” between the two sidewall surface 222s. In some embodiments, the depth D1 is in a range of 2 nm to 100 nm, 3 nm to 100 nm, 5 nm to 100 nm, 10 nm to 100 nm, or 50 nm to 100 nm. In some embodiments, the depth D1 is less than or equal to about 100 nm. In some embodiments, the width W1 is in a range of 10 nm to 50 nm, 10 nm to 30 nm, 5 nm to 20 nm, or 15 nm to 25 nm. In some embodiments, the feature 222 has an aspect ratio (D/W) in a range of 1 to 20, 5 to 20, 10 to 20, or 15 to 20.

FIG. 2B illustrates a cross-sectional view of the semiconductor device structure 200 during intermediate stages of manufacturing corresponding to optional operation 120, in accordance with some embodiments. At operation 120, one or more conformal/nonconformal layers 230 may be formed over the surfaces of the feature 222. The one or more conformal/nonconformal layers 230 can include one or more barrier, adhesion, and/or liner layers. The one or more conformal/nonconformal layers 230 can include or be a nitride, for example, silicon nitride, carbon nitride, aluminum nitride, tantalum nitride, titanium nitride, tungsten nitride, the like, or a combination thereof, or a metal, for example, tantalum, cobalt, titanium, tungsten, the like, or a combination thereof, or a carbide, for example, tungsten carbide, aluminum carbide, the like, or a combination thereof. The one or more conformal/nonconformal layers 230 may be formed by any suitable deposition process such as ALD, CVD, PVD, or a hybrid ALD/CVD process.

The one or more conformal/nonconformal layers 230 may be formed over the sidewall surface 222s and the bottom surface 222b of the feature 222 and on the upper surface 220u or field region of the dielectric layer 220. In some embodiments, the one or more conformal/nonconformal layers 230 include a barrier layer having a liner layer formed thereon, for example, a titanium nitride barrier layer having a tungsten liner formed thereon. In some embodiments, the one or more conformal/nonconformal layers 230 include a liner layer formed over the surfaces of the feature 222. The one or more conformal/nonconformal layers 230 may include or be a liner layer. The liner layer may be a tungsten liner layer. The liner layer may have an initial thickness in a range from about 1 Å to about 100 Å, or in a range from about 20 Å to about 50 Å. In some embodiments, the one or more conformal/nonconformal layers 230 may be discontinuous along for example, the sidewall surface 222s and/or the bottom surface 222b. In particular embodiments, the one or more conformal/nonconformal layers 230 include a tungsten-liner layer, which is formed via a PVD process. As depicted in FIG. 2B, the liner layer may create an overhang portion 234 along the upper surface 220u or the field region of the dielectric layer 220. The overhang portion 234 may partially obstruct or block the top opening of the feature 222. The overhang portion 234 may reduce the width of the top opening from W1 as shown in FIG. 2A to W2 as shown in FIG. 2B.

FIG. 2C illustrates a cross-sectional view of the semiconductor device structure 200 during intermediate stages of manufacturing corresponding to optional operation 130, in accordance with some embodiments. At operation 130, a nucleation layer, for example, a nucleation layer 240 is formed over the surfaces of the feature 222, for example, over the surface of the one or more conformal/nonconformal layers 230. The nucleation layer 240 may function as a seed layer for subsequent deposition of the metal film. In addition, in some embodiments where the previously deposited one or more conformal/nonconformal layers 230 are discontinuous, for example, along the sidewall surface 222s, the nucleation layer 240 may repair discontinuous portions of the one or more conformal/nonconformal layers 230. The nucleation layer 240 may include or be any suitable material for facilitating the growth of the subsequently deposited metal film. The nucleation layer 240 can include or be a metal, for example, tantalum, cobalt, titanium, tungsten, ruthenium, the like, or a combination thereof, or a metal-boride, for example, tungsten-boride, or the like. The nucleation layer 240 may be formed by a nucleation layer deposition process 242. Any suitable nucleation layer deposition process such as ALD, CVD, PVD, or a hybrid ALD/CVD process may be used.

In some embodiments, the nucleation layer 240 may include or be a tungsten-containing nucleation layer, for example, a boron-tungsten (BW) nucleation layer, a boron-silicon-tungsten (BSW) nucleation layer, or a silicon-tungsten (SW) nucleation layer. The nucleation layer 240 may be a conformal layer. In some embodiments, the one or more conformal/nonconformal layers 230 include a barrier and/or liner layer having the nucleation layer 240 formed thereon, for example, a tungsten liner layer having a boron-tungsten nucleation layer formed thereon. In some embodiments, the one or more conformal/nonconformal layers 230 and the nucleation layer 240 may be referred to individually or together as tungsten-containing layers or the underlying layers 246 as depicted in FIG. 2C.

In some embodiments where the nucleation layer 240 is a tungsten-containing nucleation layer, forming the nucleation layer 240 at operation 130 includes exposing the semiconductor device structure 200 to a tungsten-containing precursor gas at a first precursor gas flow rate followed by exposing the semiconductor device structure 200 to a reducing agent. The reducing agent may include boron and is introduced to the processing region at a reducing agent flow rate. The tungsten-containing precursor gas and the reducing agent may be alternated cyclically to form the nucleation layer 240 over the semiconductor device structure 200 within the feature 222 at the reducing agent flow rate. The reducing agent and the tungsten-containing precursor gas may be cyclically alternated, beginning with either the reducing agent or the tungsten-containing precursor gas, and ending with the same beginning gas or ending with a gas different from the beginning gas. In some embodiments, the reducing agent or the tungsten-containing precursor gas are cyclically alternated beginning with the tungsten-containing precursor gas and ending in the reducing agent.

In some embodiments, the nucleation layer 240 is deposited using an ALD process. The ALD process includes repeating cycles of alternately exposing the feature 222 to a tungsten-containing precursor and exposing the feature 222 to a reducing agent. In some embodiments, the processing region is purged between the alternating exposures. In some embodiments, the processing region is continuously purged. Examples of suitable tungsten-containing precursors include tungsten halides, such as tungsten hexafluoride (WF₆), tungsten hexachloride (WCl₆), or a combination thereof. In some embodiments, the tungsten-containing precursor includes WF₆, and the reducing agent includes a boron-containing agent, such as B₂H₆. In some embodiments, the tungsten-containing precursor includes an organometallic precursor and/or a fluorine-free precursor, for example, MDNOW (methylcyclopentadienyl-dicarbonylnitrosyl-tungsten), EDNOW (ethylcyclopentadienyl-dicarbonylnitrosyl-tungsten), tungsten hexacarbonyl (W(CO)₆), or a combination thereof.

In some embodiments, during the nucleation layer deposition process 242, the processing region is maintained at a pressure of less than about 120 Torr, such as in a range from about 900 mTorr to about 120 Torr, in a range from about 1 Torr to about 100 Torr, or for example, in a range from about 1 Torr to about 50 Torr. Exposing the semiconductor device structure 200 to the tungsten-containing precursor includes flowing the tungsten-containing precursor into the processing region at a flow rate of about 100 sccm or less, such as in a range from about 10 sccm to about 60 sccm, or in a range from about 20 sccm to about 80 sccm. Exposing the semiconductor device structure 200 to the reducing agent includes flowing the reducing agent into the processing region at a flow rate in a range from about 200 sccm to about 1000 sccm, such as in a range from about 300 sccm to about 750 sccm. It should be noted that the flow rates for the various deposition and treatment processes described herein are for a processing system configured to process a 300 mm diameter substrate. Appropriate scaling may be used for processing systems configured to process different-sized substrates.

In some embodiments, the tungsten-containing precursor and the reducing agent are each flowed into the processing region for a duration in a range from about 0.1 seconds to about 10 seconds, such as in a range from about 0.5 seconds to about 5 seconds. The processing region may be purged between the alternating exposures by flowing a purge gas, such as argon (Ar) or hydrogen gas, into the processing region for a duration in a range from about 0.1 seconds to about 10 seconds, such as in a range from about 0.5 seconds to about 5 seconds. Typically, the repeating cycles of the nucleation process continue until the nucleation layer 240 has a thickness in a range from about 10 Å to about 200 Å, such as in a range from about 10 Å to about 150 Å, or in a range from about 20 Å to about 150 Å. In one example, the ALD cycle is repeated for 3 to 5 cycles. The nucleation layer 240 is disposed along sidewall surface 222s and or the bottom surfaces 222b of the feature 222, such as over the one or more conformal/nonconformal layers 230. The nucleation layer 240 may also contribute to the thickness of the overhang portion 234 formed by the liner layer during operation 120.

Before exposure to the hydrogen plasma treatment process 252, the semiconductor device structure 200 has overhang portion 234. Overhang portion 234 can be measured as a distance from the sidewall surface 222 to the edge of the overhang portion 234. In some embodiments, the overhang portion 234 has a thickness in a range of about 1 nm to about 20 nm, in a range of about 1 nm to about 10 nm, or in a range of about 1 nm to about 5 nm. In some embodiments, the overhang portion 234 has a thickness of less than or equal to about 20 nm, less than or equal to about 10 nm, or less than or equal to about 5 nm. In some embodiments, the overhang portion has a thickness of about 3 nm.

FIG. 2D illustrates a cross-sectional view of the semiconductor device structure 200 during intermediate stages of manufacturing corresponding to operation 140, in accordance with some embodiments. At operation 140, the semiconductor device structure 200 is exposed to a hydrogen plasma treatment process 252. The hydrogen plasma treatment process 252 utilizes ion based hydrogen plasma to achieve conformal treatment by treating a first portion 254 along the upper surface 220u or field region, the overhang portion 234, and inside the feature 222 along the sidewall surface 222s while leaving a second portion (i.e., the bottom surface 222b) substantially untreated. The hydrogen plasma treatment on the first portion 254 suppresses growth of the subsequently deposited metal film on the treated regions (e.g., the upper surface 222u, the overhang portion 234, and/or the sidewall surface 222s) while enabling bottom-up growth from the bottom surface 222b. The first portion 254 may be partially formed along the length “L1” of the sidewall surface 222s. For example, referring to FIG. 2D, the first portion 254 may be formed in a range about 10% to about 50% of “L1,” or in a range of about 15% to about 40% of “L1,” or in a range of about 20% to about 30% of “L1.” The first portion is proximate to the opening of the feature 222.

As identified above, the hydrogen plasma treatment on the first portion 254 suppresses growth of the subsequently deposited metal film on the treated regions. The level of suppression can be measured as an incubation delay. Stated differently, the incubation delay is the difference in deposition behavior between a treated surface and an untreated surface.

The incubation delay can be measured as the time delay between deposition on the untreated surface and the treated surface. In this regard, the method 100 advantageously provides a short incubation delay. In some embodiments, the incubation delay is less than or equal to about 20 seconds, or less than or equal to about 10 seconds.

The incubation delay can also be measured as the thickness of film deposited on the untreated surface within the time between when deposition begins on the untreated surface and when deposition begins on the treated surface. Stated differently, when stated as a thickness, incubation delay corresponds to the thickness deposited within the corresponding incubation delay stated as a time period. The incubation delay, as a thickness, also corresponds to the amount of deposition expected on the untreated surface before deposition begins on the treated surface. In some embodiments, the incubation delay is less than or equal to about 50 Å, less than or equal to about 30 Å, or in a range of about 30 Å to about 50 Å.

In some embodiments, the semiconductor device structure 200 may be heated prior to or during the hydrogen plasma treatment 252. For example, heating the semiconductor device structure 200 at a temperature of at least about 250 degrees Celsius, or at least about 350 degrees Celsius may facilitate the efficacy of the hydrogen plasma treatment 252 of the underlying layers 246. In some embodiments, the substrate may be heated at a temperature from about 250 to about 550 degrees Celsius, or in some embodiments, from about 350 to about 450 degrees Celsius. The actual maximum substrate temperature may vary based upon hardware limitations and/or the thermal budget of the substrate being processed.

In some embodiments, during the hydrogen plasma treatment process 252 the processing region is maintained at a pressure of less than or equal to about 20 Torr, or of less than or equal to about 10 Torr, or less than or equal to about 5 Torr, or less than or equal to about 1 Torr, or less than or equal to about 20 mTorr, or less than or equal to about 10 mTorr, such as in a range from about 1 mTorr to about 20 mTorr, or in a range from about 5 m Torr to about 20 Torr, or in a range from about 1 mTorr to about 10 mTorr, or in a range from about 5 mTorr to about 10 mTorr, or in a range from about 1 Torr to about 20 Torr; or in a range from about 1 Torr to about 10 Torr, or in a range from about 1 Torr to about 5 Torr.

In some embodiments, the hydrogen plasma treatment process 252 can include exposing the underlying layers 246 to a radio frequency (RF) plasma formed from a process gas including hydrogen and optionally a noble gas. The process gas may include 1 to 20% of H₂, or 1 to 10% of H₂, or 5 to 20% of H₂, with the balance being a noble gas. In some embodiments, the process gas may be H₂ or a mixture of H₂ and a noble gas. The noble gas may be, for example, argon (Ar), helium (He), krypton (Kr), or the like. In some embodiments, the process gas includes nitrogen (N₂) and argon (Ar). In some embodiments, the process gas consists only of nitrogen (N₂) and the noble gas. In some embodiments, the process gas may be predominantly comprised of or may consist essentially of hydrogen (H₂) and the noble gas.

In some embodiments, the process gas may be supplied at a total gas flow in a range from about 100 to about 1000 sccm, or at least 300 sccm (although other flow rates may be used depending upon the application and configuration of the process chamber). In some embodiments, the process gas may include about 10-100 percent H₂, may include about 0.5-99 percent H₂, may be about 0.5-15 percent H₂, may be about 0.5-10 percent H₂, or may be about 1-5 percent H₂.

The process gas may be introduced into a processing region of a process chamber, for example, a plasma reactor, and used to form a plasma. The plasma may be formed by using an RF source power. In some embodiments, the RF source power is up to about 5000 Watts, for example, in a range from about 10 Watts to about 500 Watts. The RF source power may be provided at any suitable RF frequency. For example, in some embodiments, the RF source power may be provided at a frequency about 2 to about 60 MHz, for example, about 13.56 MHz.

In an embodiment where the plasma includes substantially hydrogen ions, the semiconductor device structure 200 is exposed to a plasma formed from a process gas including 5 to 20% hydrogen (H₂) and the remainder argon, at a partial pressure of hydrogen in a range from about 100 mTorr to about 500 mTorr, or at least 100 mTorr. Not to be bound by theory, but it is believe that performing the hydrogen plasma treatment 252 at a hydrogen partial pressure less than 100 mTorr does not provide enough hydrogen ions to ensure sufficient sidewall passivation. Similarly, performing the hydrogen plasma treatment process 252 at a hydrogen partial pressure greater than 500 mTorr provides too many hydrogen ions, which may passivate the bottom surface of the feature preventing bottom-up growth.

FIG. 2E illustrates a cross-sectional view of the semiconductor device structure 200 during intermediate stages of manufacturing corresponding to operation 150, in accordance with some embodiments. At operation 150, a metal film 264 is deposited via a bottom-up metal fill process 262 into the feature 222. In some embodiments, the bottom-up metal fill process 262 may completely fill the feature 222 as is shown in FIG. 2G.

In some embodiments, the bottom-up metal fill process 262 may only partially fill the feature 222 at operation 150 followed as shown in FIG. 2E by a hydrogen plasma treatment 272 at operation 170 as shown in FIG. 2F. The hydrogen plasma treatment 272 at operation 170 may be performed similarly to the hydrogen plasma treatment of operation 140. In some embodiments, the first portion 254 formed during operation 140 may dissipate or degrade after a certain amount of time. The hydrogen plasma treatment 272 at operation 170 reforms the treated first portion 254 on exposed surfaces over the sidewalls, the overhang portion 234, and the upper surface 222u or field region as shown in FIG. 2E. Reforming the treated first portion at operation 170 enables bottom-up metal fill to continue with the metal film 264. Operation 160 and operation 170 may be repeated until the feature 222 is filled to a targeted level as is shown in FIG. 2G.

In some embodiments, the metal film 264 is formed using a CVD process including concurrently flowing (co-flowing) a tungsten-containing precursor gas, and a reducing agent into the processing region and exposing the semiconductor device structure 200 thereto. The tungsten-containing precursor and the reducing agent used for the tungsten gap-fill CVD process may include any combination of the tungsten-containing precursors and reducing agents described herein. In some embodiments, the tungsten-containing precursor includes WF₆, and the reducing agent includes hydrogen gas. In some embodiments, the metal film 264 partially fills the features 222.

In some embodiments, the tungsten-containing precursor is flowed into the processing region at a flow rate in a range from about 10 sccm to about 1200 sccm, or more than about 50 sccm, or less than about 1000 sccm, or in a range from about 100 sccm to about 900 sccm. The reducing agent is flowed into the processing region at a rate of more than about 500 sccm, such as more than about 750 sccm, more than about 1000 sccm, or in a range from about 500 sccm and about 10000 sccm, such as in a range from about 1000 sccm to about 9000 sccm, or in a range from about 1000 sccm and about 8000 sccm.

In some embodiments, the tungsten gap-fill CVD process conditions are selected to provide a tungsten feature having a relativity low residual film stress when compared to conventional tungsten CVD processes. For example, in some embodiments, the tungsten gap-fill CVD process includes heating the substrate at a temperature of about 250° C. or more, such as about 300° C. or more, or in a range from about 250° C. to about 500° C., or in a range from about 300° C. to about 500° C. During the CVD process, the processing region may be maintained at a pressure of less than about 500 Torr, less than about 600 Torr, less than about 500 Torr, less than about 400 Torr, or in a range from about 1 Torr to about 500 Torr, such as in a range from about 1 Torr to about 450 Torr, or in a range from about 1 Torr to about 400 Torr, or for example, in a range from about 1 Torr and about 300 Torr.

In another embodiment, the metal film 264 is deposited at operation 160 using an atomic layer deposition (ALD) process. The tungsten gap-fill ALD process includes repeating cycles of alternately exposing the semiconductor device structure 200 to a tungsten-containing precursor gas and a reducing agent and purging the processing region between the alternating exposures.

The tungsten-containing precursor and the reducing agent are each flowed into the processing region for a duration of between about 0.1 seconds and about 10 seconds, such as between about 0.5 seconds and about 5 seconds. The processing region may be purged between the alternating exposures by flowing an inert purge gas, such as argon (Ar) or hydrogen, into the processing region for a duration in a range from about 0.1 seconds to about 10 seconds, such as in a range from about 0.5 seconds to about 5 seconds.

In other embodiments, the metal film 264 is deposited using a pulsed CVD method that includes repeating cycles of alternately exposing the semiconductor device structure 200 to a tungsten-containing precursor gas and a reducing gas without purging the processing region. The processing conditions for the tungsten gap-fill pulsed CVD method may be the same, substantially the same, or within the same ranges as those described above for the tungsten gap-fill ALD process.

FIG. 2H illustrates a cross-sectional view of the semiconductor device structure 200 during intermediate stages of manufacturing corresponding to operation 180, in accordance with some embodiments. At operation 180, the semiconductor device structure 200 may be exposed to additional processing 282. In some embodiments, the additional processing 282 includes a planarization process, for example a chemical mechanical polishing (CMP) process or an etchback process may be performed to remove excess portions or overburden of the conductive material (if present) on the upper surface 220u of the dielectric layer 220. After completing the planarization process, a top surface 284 of the metal film 264 may be co-planar or level with the upper surface 220u of the dielectric layer and the top surfaces of the nucleation layer 240 and the one or more conformal/nonconformal layers 230 as is shown in FIG. 2H. In some embodiments, an annealing process may be performed during operation 180.

In some embodiments, as is shown in FIG. 2H, the one or more conformal/nonconformal layers 230, the nucleation layer 240, and the metal gap-fill material 264 are monolithic and do not have an interface therebetween. The metal film 264, the one or more conformal/nonconformal layers 230, and the nucleation layer 240 together form a metal gap-fill layer or tungsten-containing layer.

Examples of a processing system that may be suitably modified in accordance with the teachings provided herein include an integrated processing system or other suitable processing systems commercially available from Applied Materials, Inc., located in Santa Clara, California. It is contemplated that other processing systems (including those from other manufacturers) may be adapted to benefit from aspects described herein.

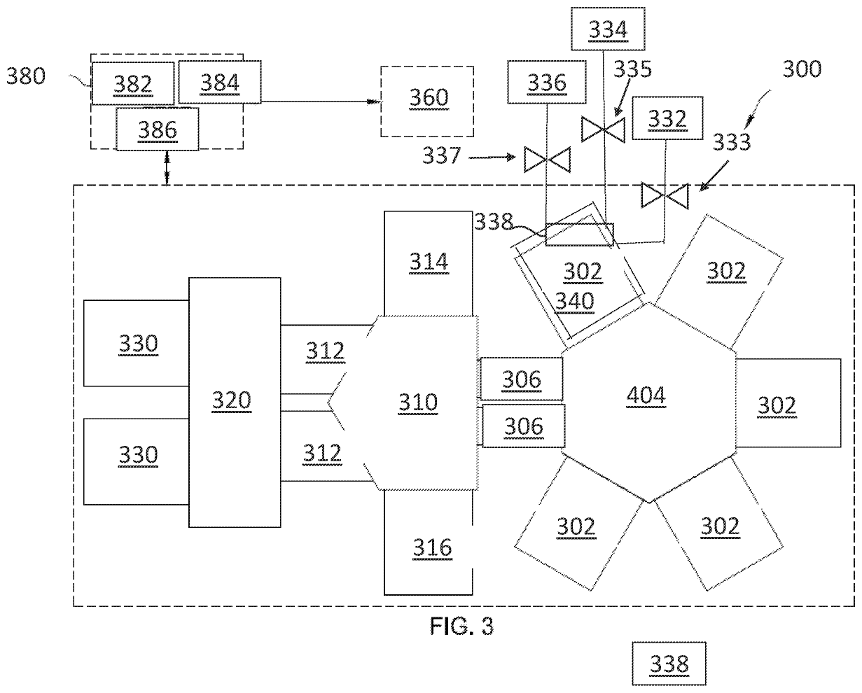

FIG. 3 illustrates a schematic top-view diagram of an example multi-chamber processing system 300 or cluster tool that can be used to complete a hydrogen plasma treatment followed by formation of a metal film according to implementations of the present disclosure. As shown in FIG. 3, a plurality of process chambers 302 is coupled to a first transfer chamber 304. The first transfer chamber 304 is also coupled to a first pair of pass-through chambers 306. The first transfer chamber 304 has a centrally disposed transfer robot (not shown) for transferring substrates between the pass-through chambers 306 and the process chambers 302. The pass-through chambers 306 are coupled to a second transfer chamber 310, which is coupled to a process chamber 314 that is configured to perform pre-clean process and a process chamber 316 that is configured to perform an epitaxial or alternatively, a PVD deposition process. The second transfer chamber 310 has a centrally disposed transfer robot (not shown) for transferring substrates between a set of load lock chamber 312 and the process chamber 314 or the process chamber 316. A factory interface 320 is connected to the second transfer chamber 310 by the load lock chambers 312. The factory interface 320 is coupled to one or more pods 330 on the opposite side of the load lock chambers 312. The pods 330 typically are front opening unified pods (FOUP) that are accessible from a clean room.

Prior to various operations, a substrate may first be transferred to the process chamber 314 where a pre-clean process is performed to remove contaminant, such as carbon or oxide contaminant from exposed surface of a source/drain region of a transistor of the substrate.

The substrate is then transferred to one or more of the process chambers 302. In some implementations, the process chamber 302 may etch a via or a trench in the substrate. In some implementations, the substrate is provided to an etch chamber, which is not a part of the processing system that contains the process chambers 314, 316 and the one or more process chambers 302, to perform the trench formation process. In other operations, the substrate is provided with trenches formed therein. Once the trench is formed in the dielectric material, the substrate is transferred to the process chamber 314 for cleaning.

Then the substrate is transferred to the process chamber 316 and/or at least one of the process chambers 302 where operations are performed. For example, in some embodiments, the substrate may be transferred to at least one of the process chambers 302 where a metal deposition operation is performed to form a seed layer. The metal can be deposited in any suitable chamber such as a PVD, atomic layer deposition (ALD), epitaxial (EPI) or other suitable chamber.

The substrate may be transferred to one of the process chambers 302 where a hydrogen plasma treatment operation may be performed. The hydrogen plasma treatment may be performed in an conductively coupled plasma (CCP) reactor or other suitable plasma process chamber.

The substrate can then be transferred to one of the process chambers 302 or 316 where a gap-fill operation is performed. The gap-fill operation may be performed in a CVD, ALD or other suitable chamber. For example, process chamber 302 or 316 may deposit a metal such as tungsten or other suitable material for growth at the bottom of the trench or feature for forming a portion of a microelectronic device.

A system controller 380 is coupled to the processing system 300 for controlling the processing system 300 or components thereof. For example, the system controller 380 may control the operations of the processing system 300 using a direct control of the process chambers 302, 304, 306, 310, 312, 314, 316, 320, 330 of the processing system 300 or by controlling controllers associated with the process chambers 302, 304, 306, 310, 312, 314, 316, 320, 330, 360. In operation, the system controller 380 enables data collection and feedback from the respective chambers to coordinate performance of the processing system 300.

The system controller 380 generally includes a central processing unit (CPU) 382, memory 384, and support circuits 386. The CPU 382 may be one of any form of a general purpose processor that can be used in an industrial setting. The memory 384, non-transitory computer-readable medium, or machine-readable storage device, is accessible by the CPU 382 and may be one or more of memory such as random access memory (RAM), read only memory (ROM), floppy disk, hard disk, or any other form of digital storage, local or remote. The support circuits 386 are coupled to the CPU 382 and may comprise cache, clock circuits, input/output subsystems, power supplies, and the like. The various implementations disclosed in this disclosure may generally be implemented under the control of the CPU 382 by executing computer instruction code stored in the memory 384 (or in memory of a particular process chamber) as, e.g., a computer program product or software routine. That is, the computer program product is tangibly embodied on the memory 384 (or non-transitory computer-readable medium or machine-readable storage device). When the computer instruction code is executed by the CPU 382, the CPU 382 controls the chambers to perform operations in accordance with the various implementations.

The system controller 380 is configured to perform methods such as the method 100 stored in the memory 384.

In some embodiments, the first process chamber 302 includes a hydrogen gas source 332 that is fluidly coupled to a processing region 340 of the first process chamber 302, wherein the hydrogen gas source 332 is configured to deliver hydrogen gas to the processing region 340. The first process chamber 302 may further include a first flow control valve 333 that is configured to control the flow of hydrogen gas provided from the hydrogen gas source 332 to the processing region 340. In some embodiments, the first process chamber 302 further includes a non-reactive gas source 334 that is fluidly coupled to the processing region 340 of the first process chamber 302, wherein the non-reactive gas source 334 is configured to deliver a noble or inert gas to the processing region 340. The first process chamber 302 may further include a second flow control valve 335 that is configured to control the flow of the non-reactive gas provided from the non-reactive gas source 334 to the processing region 340. The first process chamber 302 may further include a capacitively coupled plasma source 338 that is configured to generate a plasma in the processing region 340, wherein the plasma is formed from the hydrogen gas and the non-reactive gas.

In some embodiments, the system controller 380 is configured to control the first flow control valve 333 and the second flow control valve 335 so that an amount of hydrogen gas and non-reactive gas are provided to the processing region 340 of the first process chamber 302, to preferentially treat one or more tungsten-containing layers disposed on a field region and sidewalls of features formed in the substrate by generating plasma in the processing region 340 of first process chamber 302.

Embodiments and all of the functional operations described in this specification can be implemented in digital electronic circuitry, or in computer software, firmware, or hardware, including the structural means disclosed in this specification and structural equivalents thereof, or in combinations of them. Embodiments described herein can be implemented as one or more non-transitory computer program products, i.e., one or more computer programs tangibly embodied in a machine readable storage device, for execution by, or to control the operation of, data processing apparatus, e.g., a programmable processor, a computer, or multiple processors or computers.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

The term “data processing apparatus” encompasses all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, or a combination of one or more of them. Processors suitable for the execution of a computer program include, by way of example, both general and special purpose microprocessors, and any one or more processors of any kind of digital computer.

Computer readable media suitable for storing computer program instructions and data include all forms of nonvolatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A method for processing a semiconductor device, the method comprising:
generating a hydrogen plasma within a processing region;
filtering the hydrogen plasma to provide substantially only hydrogen ions;
exposing a first portion of a metal layer to the hydrogen ions to treat the first portion of the layer without treating a second portion of the layer; and
selectively forming a metal film on the second portion of the metal layer.

2. The method of claim 1, wherein the hydrogen plasma is a conductively coupled plasma (CCP).

3. The method of claim 1, wherein the hydrogen plasma is formed from hydrogen gas (H₂).

4. The method of claim 3, wherein hydrogen gas is provided at a flow rate of at least 300 sccm.

5. The method of claim 3, wherein the partial pressure of the hydrogen gas is at least 100 mTorr.

6. The method of claim 1, wherein the metal layer is a tungsten nucleation layer.

7. The method of claim 1, wherein the metal film comprises tungsten.

8. The method of claim 1, wherein the method provides an incubation delay of less than 20 seconds on the first portion of the metal layer.

9. The method of claim 1, wherein the method provides an incubation delay in a range of about 30 Å to about 50 Å on the first portion of the metal layer.

10. A method of bottom-up metal gapfill, the method comprising:
exposing a metal nucleation layer to ions from a hydrogen-containing plasma to form a treated portion of the nucleation layer, the nucleation layer being formed on sidewall surfaces and a bottom surface of a feature, the feature extending a depth from a top to the bottom surface and having the sidewall surfaces therebetween, the treated portion being located on the sidewall surfaces near the top; and
forming a metal film on the untreated portion of the nucleation layer on the bottom surface.

11. The method of claim 10, wherein the hydrogen-containing plasma is a CCP plasma formed from hydrogen gas.

12. The method of claim 11, wherein hydrogen gas is provided at a flow rate of at least 300 sccm and has a partial pressure of at least 100 mTorr.

13. The method of claim 10, wherein the metal layer is a tungsten nucleation layer.

14. The method of claim 10, wherein the metal film comprises tungsten.

15. The method of claim 10, wherein the metal film contains substantially no seam or voids.

16. The method of claim 10, wherein the method provides an incubation delay in a range of about 30 Å to about 50 Å on the treated portion of the nucleation layer.

17. A method of forming a logic device, the method comprising:
providing a substrate having a feature with a tungsten layer thereon, the feature extending a depth from a top surface to a bottom surface, the feature bounded by two sidewalls, the tungsten layer being formed on at least the two sidewalls and the bottom surface of the feature;
exposing the tungsten layer to ions from a CCP hydrogen plasma to treat a portion of the tungsten layer on the sidewalls near the top surface; and
depositing a tungsten film on the untreated portion of the tungsten layer on at least the bottom surface.

18. The method of claim 17, wherein the method provides an incubation delay in a range of about 30 Å to about 50 Å on the treated portion of the tungsten layer.

19. The method of claim 17, wherein the tungsten layer has an overhang of less than or equal to about 50 Å.

20. The method of claim 17, wherein the tungsten film fills the feature with substantially no seam or void.
